(19) United States
(12) Patent Application Publication
(10) Pub. No.: US 2012/0286130 A1
(43) Pub. Date: Nov. 15, 2012

(54) CABLE MANAGEMENT APPARATUS

(75) Inventors: CHIN-WEN YEH, Tu-Cheng (TW); YANG XIAO, Wuhan City (CN); CHENG YUAN, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/372,588

(22) Filed: Feb. 14, 2012

(30) Foreign Application Priority Data
May 12, 2011 (CN) 201110122478.8

(51) Int. Cl. H05K 7/20; B65D 63/12; H05K 7/14; F16L 3/08

(52) U.S. Cl. 248/674; 24/16 PB; 248/220.21

(57) ABSTRACT

A cable management apparatus used in an electronic device is disclosed. The cable management apparatus includes a cable holder, and the cable holder includes a belt; a latching portion; and an installing portion including an elastic neck portion and an elastic head portion extending from the elastic neck portion. The latching portion is connected between the belt and the installing portion, and the belt is bent to engage with the latching portion and adapted to fasten a plurality of cables. The elastic head portion is adapted to be inserted out of a hole defined in a mounting frame and engaged with edges of the hole, and the elastic neck portion is adapted to be received in the hole.

### BACKGROUND

1. Technical Field

The present disclosure relates to cable management apparatuses, and particularly to a cable management apparatus used in an electronic device.

2. Description of Related Art

Many electronic devices, such as computers, need a plurality of cables. The cables may include, for example, power cables, data cables, communication lines, or keyboard lines. It is desirable to include some type of cable management apparatus, such as a binding accessory, that allows the various cables to be collected together and attached in a position to improve the use of space and the ease of visual examination inside an electronic device. However, the conventional binding accessory may not be suitable for temporary use in securing cables, and may often need to replace or re-route the plurality of cables. Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a cable management apparatus.

FIG. 2 is an isometric view of a cable holder of FIG. 1.

FIG. 3 is similar to FIG. 2, but shown another working state.

FIG. 4 is an assembled, isometric view of assembled cable management apparatus of FIG. 1.

FIG. 5 is an enlarged view of a circled portion V of FIG. 4.

FIG. 6 is similar to FIG. 4, but viewed from another angle.

FIG. 7 is an enlarged view of a circled portion VII of FIG. 6.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

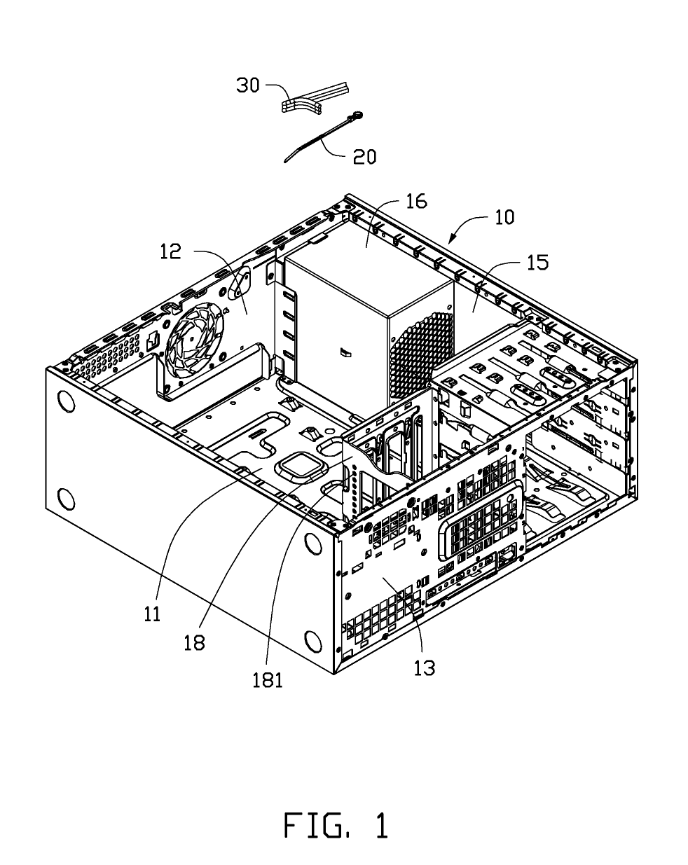

Referring to FIG. 1, a cable management apparatus in accordance with an embodiment includes an enclosure 10 and a cable holder 20. In one embodiment, the enclosure 10 is a computer enclosure.

The enclosure 10 includes a bottom plate 11, a rear plate 12, a front plate 13, and a side plate 15. A power supply 16 is secured to a first corner between the rear plate 12 and the side plate 15. A mounting frame 18 is secured to a second corner between the bottom plate 11 and the rear plate 12. The mounting frame 18 defines a plurality of holes 181. In one embodiment, the mounting frame 18 is for receiving a hard disk drive, the plurality of holes 181 maybe an air vent or a threaded hole. A plurality of cables 30 are placed in the enclosure 10.

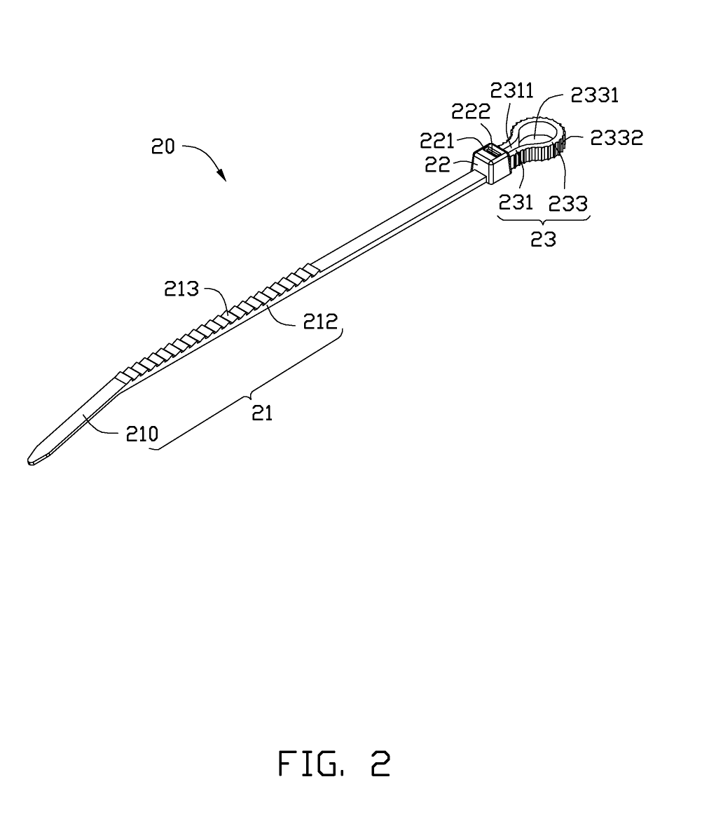

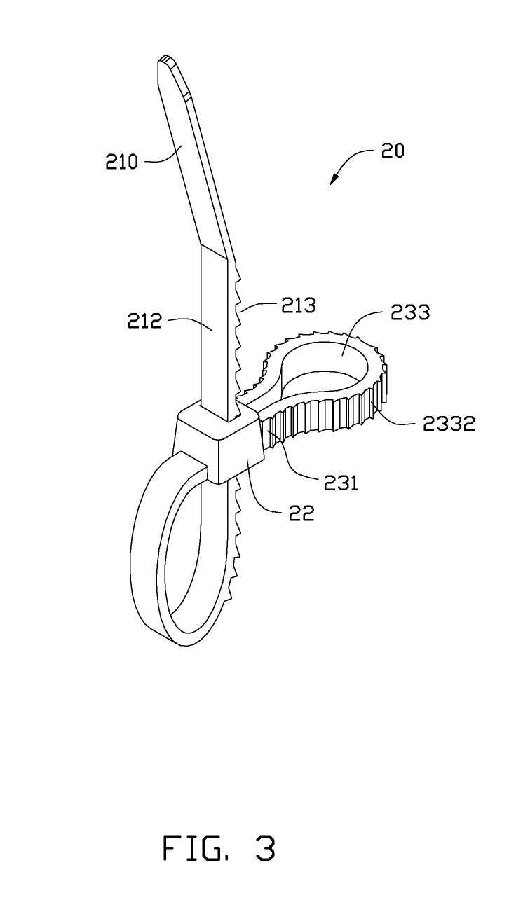

Referring to FIGS. 2 and 3, The cable holder 20 includes a belt 21, a latching portion 22 extending from the belt 21, and an installing portion 23 extending from the latching portion 22. The latching portion 22 is located between the belt 21 and the installing portion 23. The belt 21 includes a body 212 and an inserting piece 210 extending from the body 212. The body 212 is connected to the latching portion 22. The latching portion 22 defines a plurality of latching slots 213. In one embodiment, the plurality of latching slots is wedge-shaped. An obtuse angle is defined between the body 212 and the inserting piece 210. The latching portion 22 defines a latching hole 221. An elastic tongue 222 is located in the latching hole 221. The elastic tongue 222 can be engaged in the plurality of latching slots 213. The installing portion 23 includes a neck portion 231 and an elastic head portion 233. The neck portion 231 is connected to the latching portion 22, and the elastic head portion 233 is connected to the neck portion 231. The neck portion 231 defines a first through hole 2311. The elastic head portion 233 defines a second through hole 2331. The first through hole 2311 communicates with the second through hole 2331. A plurality of wedge shaped teeth 2332 is located on an outer surface of each of the elastic head portion 233 and the neck portion 231. In one embodiment, the elastic head portion 233 is an ellipse.

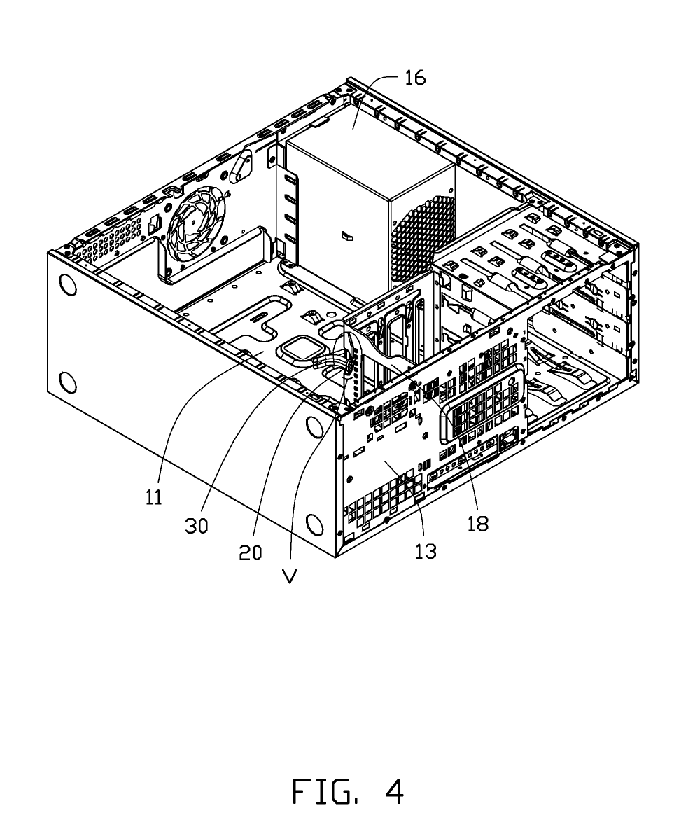

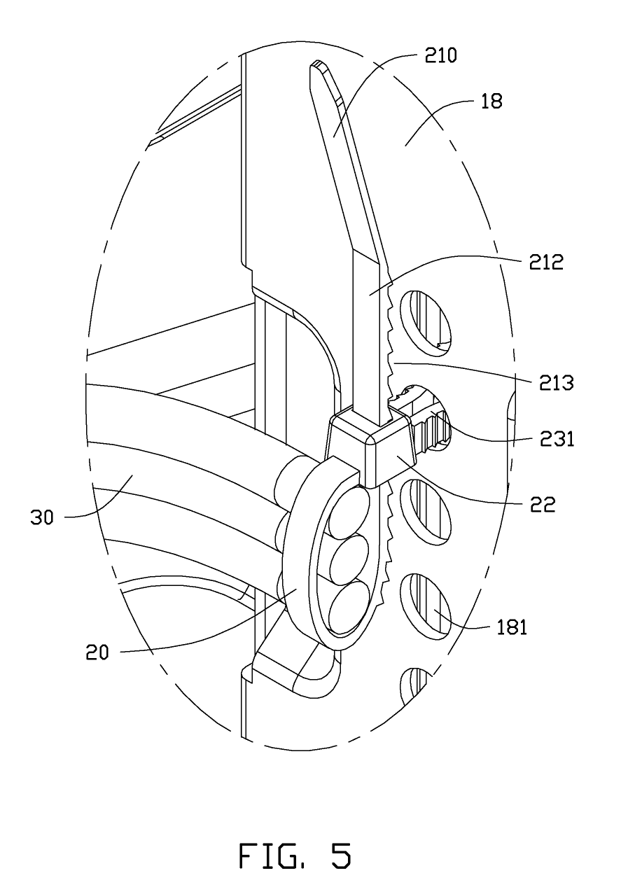

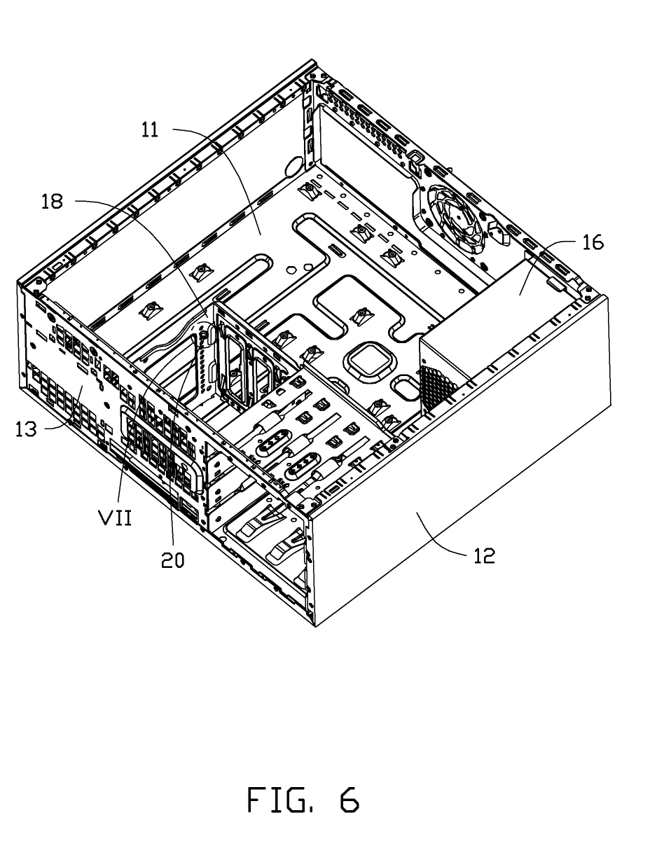

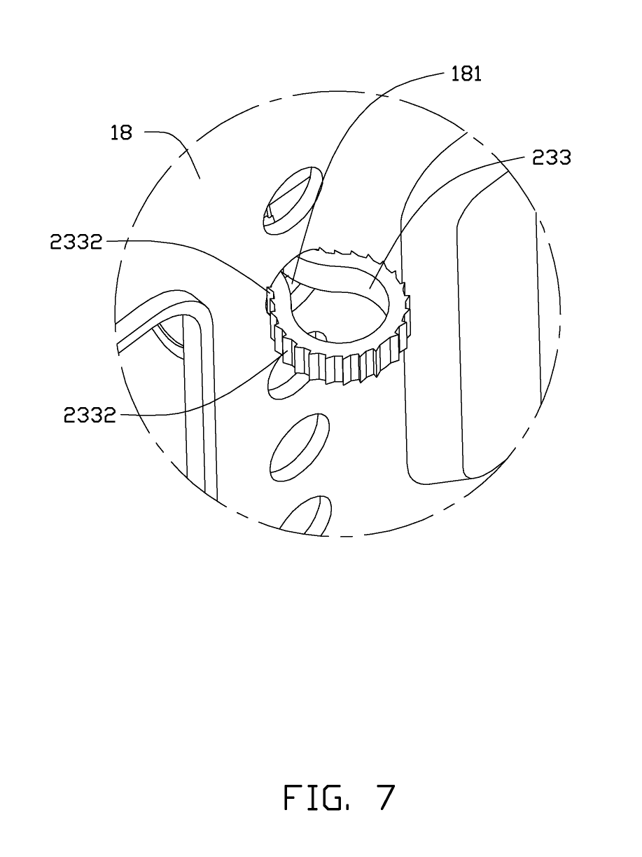

Referring to FIGS. 4-7, in use, the cable holder 20 is moved to adjacent to the plurality cables 30. The belt 21 is bent to surround the plurality of cables 30, and the inserting piece 210 is aligned to the latching hole 221. The inserting piece 210 is inserted out of the latching hole 221, and the elastic tongue 222 is inserted into the latching hole 221 to elastically deform the elastic tongue 222. The elastic tongue 222 rebounds to engage in one of the plurality of latching slots 213 until the plurality of cables 30 are fastened by the body 212.

In assembly, the installing portion 23 is moved to adjacent to the plurality of holes 181. The elastic head portion 233 is pressed to be elastically deformed and inserted out of the plurality of holes 181. Until the neck portion 231 is located in the plurality of holes 181, the elastic head portion 233 rebounds to engage with the mounting frame 18. Adjacent two of the plurality of wedge shaped teeth 2332 engage edges of each of the plurality of holes 181 therebetween. The plurality of cables 30 are secured to the mounting frame 18 then. In this position, the elastic head portion 232 and the latching portion 22 is located on two opposite sides of the mounting frame 18.

In disassembly, the elastic head portion 233 is pressed to be elastically deformed and disengaged from the plurality of holes 181, and then the plurality of cables 30 are removed from the mounting frame 18.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A cable management apparatus, comprising:
a cable holder, and the cable holder comprising:
a belt;
a latching portion; and
an installing portion comprising an elastic neck portion and an elastic head portion extending from the elastic neck portion;
wherein the latching portion is connected between the belt and the installing portion, and the belt is bent to engage with the latching portion and adapted to fasten a plurality of cables; the elastic head portion is adapted to be inserted out of a hole defined in a mounting frame and engaged with edges of the hole, and the elastic neck portion is adapted to be received in the hole.

2. The cable management apparatus of claim 1, wherein a plurality of teeth is located on the elastic head portion, and two adjacent of the plurality of teeth are adapted to engage the edges of the hole of the mounting frame therebetween.

3. The cable management apparatus of claim 1, wherein the belt comprises a body and an inserting piece, a first end of the body is connected to the latching portion, and the inserting piece extends from a second end of the body opposite to the first end; the body is engaged with the latching portion.

4. The cable management apparatus of claim 3, wherein the body defines a plurality of latching slots, the latching portion defines a latching hole, and an elastic tongue is located in the latching hole; the inserting piece is inserted through the latching hole, and the elastic tongue is engaged in one of the plurality of latching slots.

5. The cable management apparatus of claim 3, wherein an angle is defined between the body and the inserting piece, and the angle is obtuse.

6. The cable management apparatus of claim 1, wherein the elastic head portion is substantially ellipse.

7. The cable management apparatus of claim 1, wherein the elastic neck portion defines a first through hole, the elastic head portion defines a second through hole, and the first through hole communicates with the second through hole.

8. A cable management apparatus, comprising:
a mounting frame defining a hole; and
a cable holder, and the cable holder comprising:
a belt;
a latching portion; and
an installing portion comprising a neck portion and an elastic head portion extending from the neck portion;
wherein the latching portion is connected between the belt and the installing portion, and the belt is bent to engage with the latching portion and adapted to fasten a plurality of cables; the elastic head portion is inserted out of the hole and engaged with edges of the hole, and the neck portion is received in the hole.

9. The cable management apparatus of claim 8, wherein the elastic head portion and the latching portion are located in two opposite sides of the mounting frame.

10. The cable management apparatus of claim 8, wherein the hole of the mounting frame is an air vent or a threaded hole.

11. The cable management apparatus of claim 8, wherein the elastic head portion is elastically deformed when the elastic head portion is being inserted into the hole, and the elastic head portion rebounds to be engaged with the mounting frame when the elastic head portion is inserted through the hole of the mounting frame.

12. The cable management apparatus of claim 8, wherein a plurality of teeth is located on the elastic head portion, and two adjacent of the plurality of teeth are adapted to engage the edges of the hole of the mounting frame therebetween.

13. The cable management apparatus of claim 8, wherein the belt comprises a body and an inserting piece, a first end of the body is connected to the latching portion, and the inserting piece extends from a second end of the body opposite to the first end; the body is engaged with the latching portion.

14. The cable management apparatus of claim 13, wherein the body defines a plurality of latching slots, the latching portion defines a latching hole, and an elastic tongue is located in the latching hole; the inserting piece is inserted through the latching hole, and the elastic tongue is engaged in one of the plurality of latching slots.

15. The cable management apparatus of claim 13, wherein an angle is defined between the body and the inserting piece, and the angle is obtuse.

16. The cable management apparatus of claim 8, wherein the elastic head portion is substantially ellipse.

17. The cable management apparatus of claim 8, wherein the neck portion defines a first through hole, the elastic head portion defines a second through hole, and the first through hole communicates with the second through hole.

18. The cable management apparatus of claim 8, wherein the mounting frame is adapted to secure a hard disk drive or a fan.
